(19) United States
(12) Patent Application Publication
(10) Pub. No.: US 2026/0047127 A1
(43) Pub. Date: Feb. 12, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Ya-Hsin Huang, Tainan City (TW); Hao-Ping Yan, Tainan City (TW); Chun-Lin Chen, Tainan City (TW); Chin-Chia Kuo, Tainan City (TW); Ming-Hua Tsai, Tainan City (TW)

(73) Assignee: UNITED MICROELECTRONICS CORP., Hsin-Chu City (TW)

(21) Appl. No.: 18/829,332

(22) Filed: Sep. 10, 2024

(30) Foreign Application Priority Data
Aug. 8, 2024 (CN) 202411081077.6

(51) Int. Cl. H01L 29/78; H01L 21/302; H01L 27/088; H01L 29/10; H01L 29/423; H01L 29/66

(52) U.S. Cl. CPC H10D 30/608; H01L 21/302; H10D 30/0221; H10D 62/292; H10D 64/518; H10D 84/83

(57) ABSTRACT

A semiconductor device includes a substrate, a gate structure, a drain region and a source region. The substrate includes a first step structure. The first step structure includes a first step portion, a connecting portion and a second step portion arranged sequentially along a direction, and the second step portion is higher than the first step portion. The gate structure is disposed on the connecting portion. The drain region is disposed in the first step portion. The source region is disposed in the second step portion.

### BACKGROUND OF THE INVENTION

### 1. Field of the Invention

The present disclosure relates to the field of semiconductor devices, and more particularly, to a semiconductor device with a drain region and a source region located at different heights and a method for fabricating the same.

### 2. Description of the Prior Art

In order to reduce production cost, improve competitive advantages and meet the needs of various products, the miniaturization of semiconductor devices has become the development trend and focus. However, with the miniaturization of semiconductor devices, some problems may arise. For example, when the drain region and the source region are too close and a high voltage is applied, punch-through in a transistor is prone to happen. Therefore, how to improve semiconductor devices and method for fabricating the same has become an important issue for relevant industries.

### SUMMARY OF THE INVENTION

According to an embodiment of the present disclosure, a semiconductor device includes a substrate, a gate structure, a drain region and a source region. The substrate includes a first step structure. The first step structure includes a first step portion, a connecting portion and a second step portion arranged sequentially along a direction, and the second step portion is higher than the first step portion. The gate structure is disposed on the connecting portion. The drain region is disposed in the first step portion. The source region is disposed in the second step portion.

According to another embodiment of the present disclosure, a method for fabricating a semiconductor device includes steps as follows. A substrate is provided. The substrate includes a first step structure. The first step structure includes a first step portion, a connecting portion and a second step portion arranged sequentially along a direction, and the second step portion is higher than the first step portion. A gate structure is formed on the connecting portion. A drain region is formed in the first step portion. A source region is formed in the second step portion.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7, FIG. 8, FIG. 9 and FIG. 10 are schematic cross-sectional views showing steps for fabricating a semiconductor device according to an embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

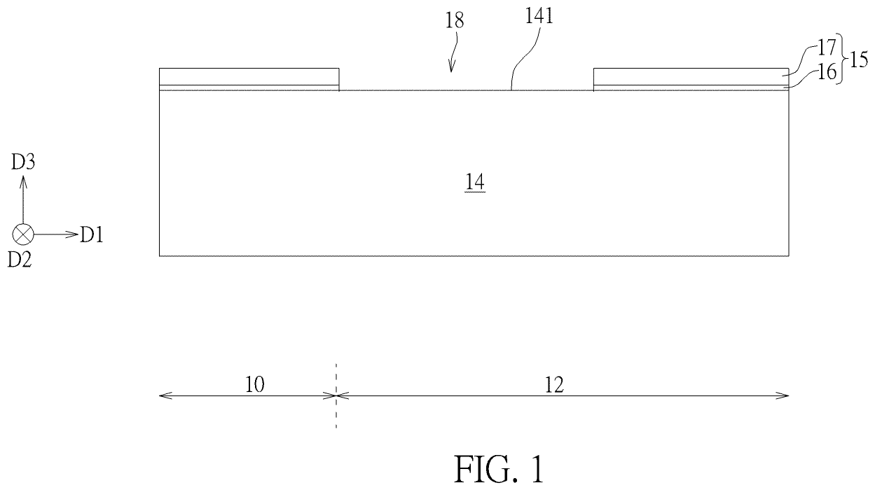

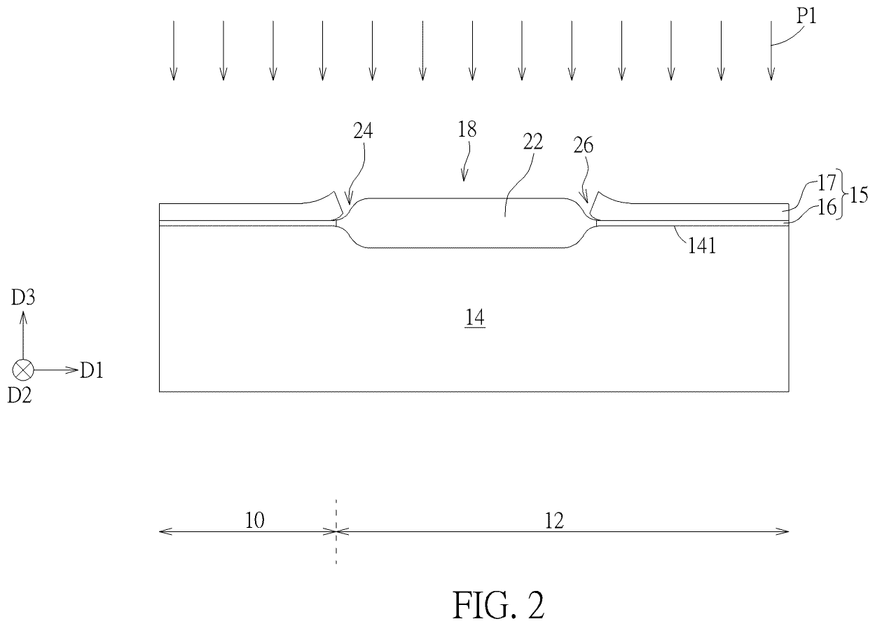

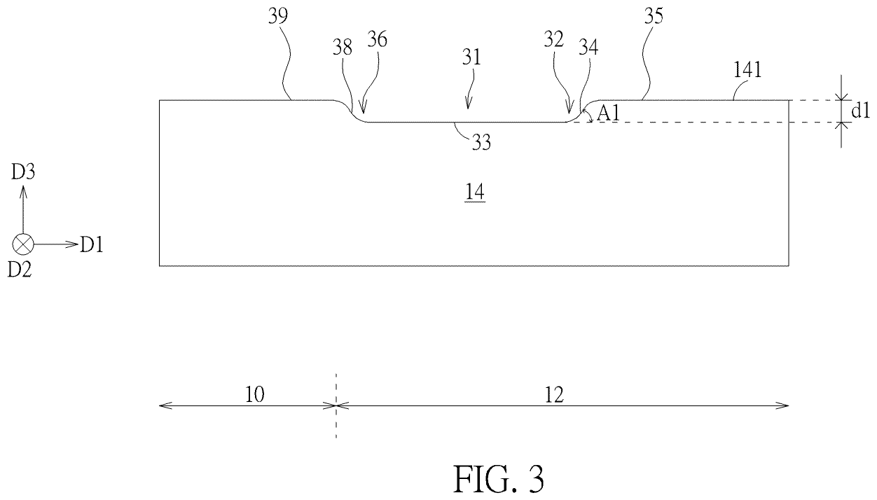

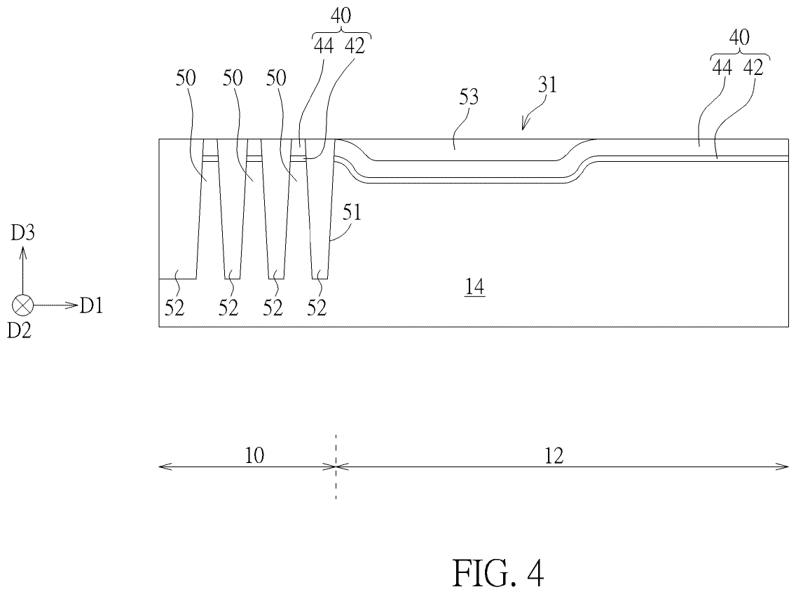

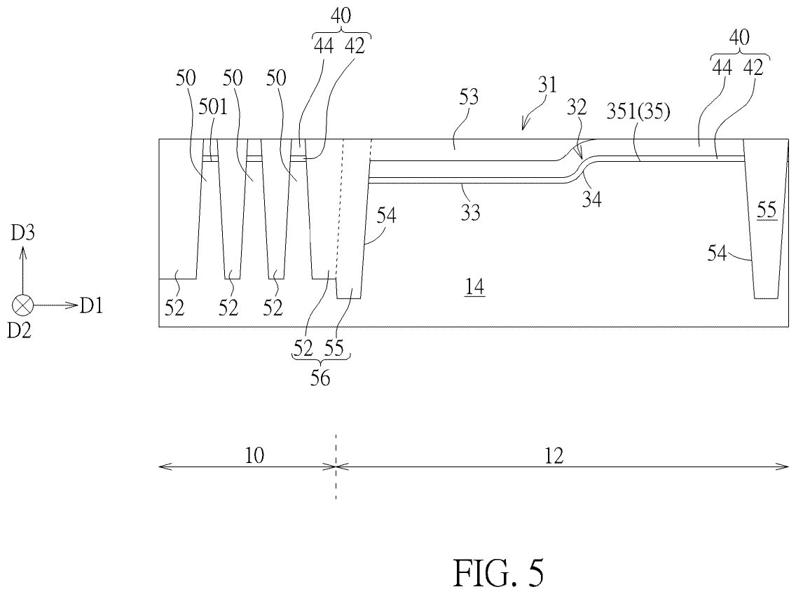

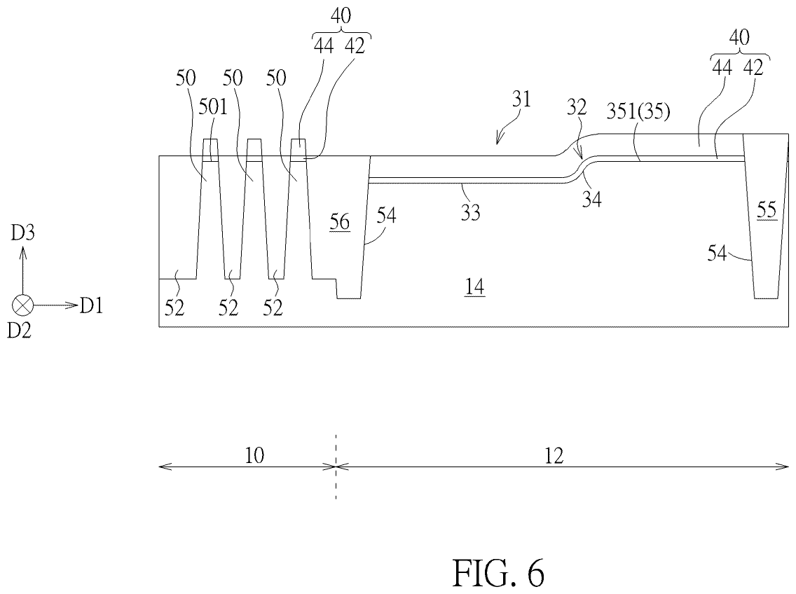

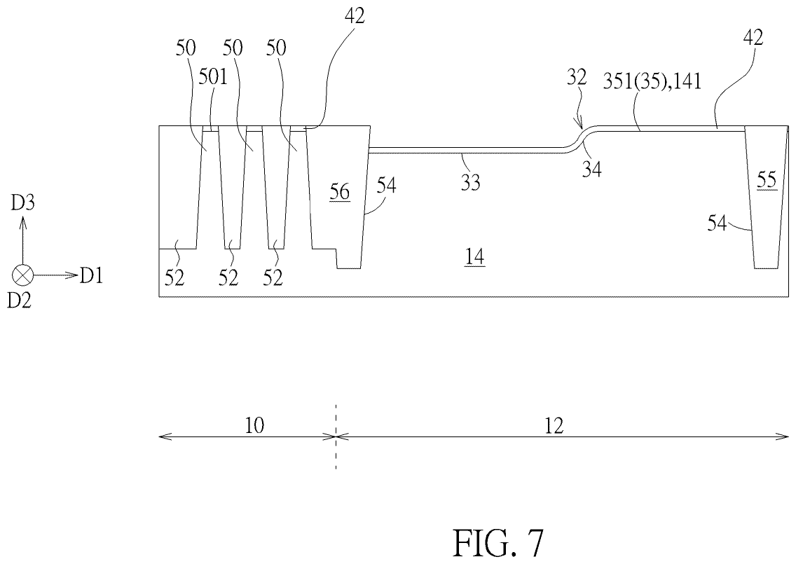

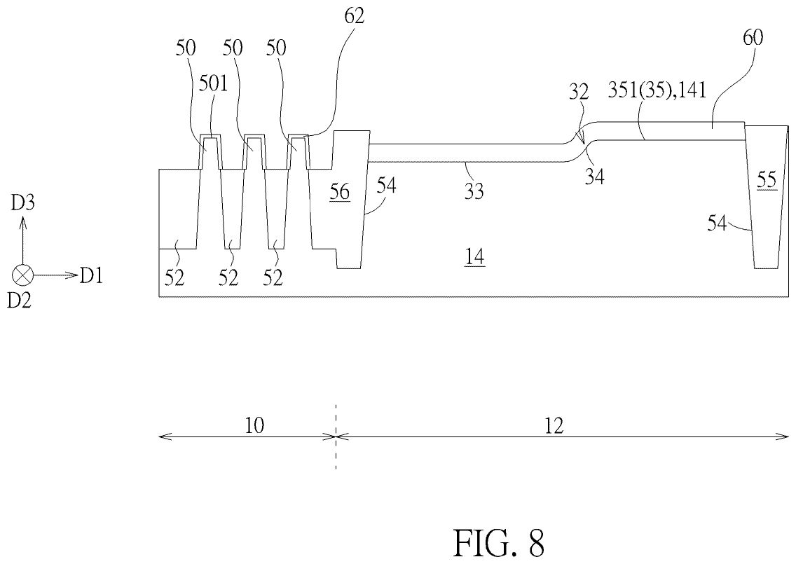

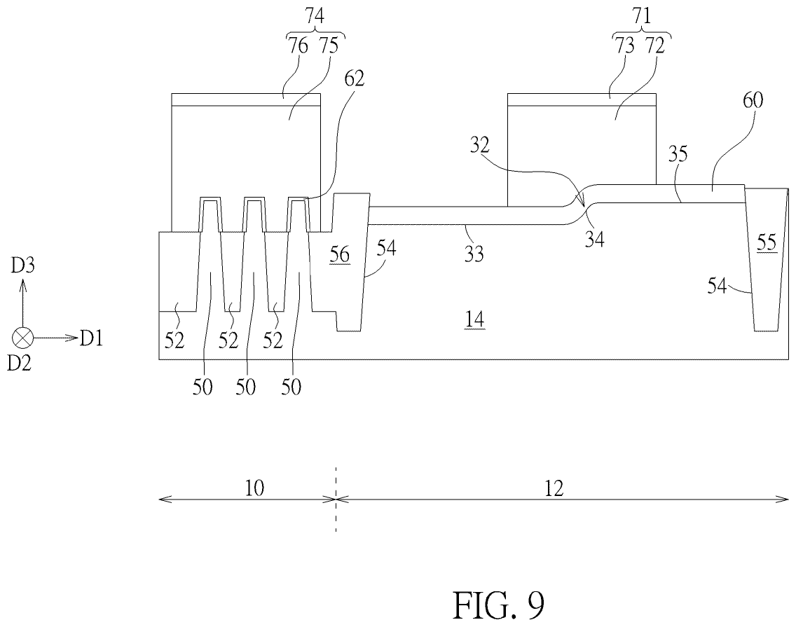

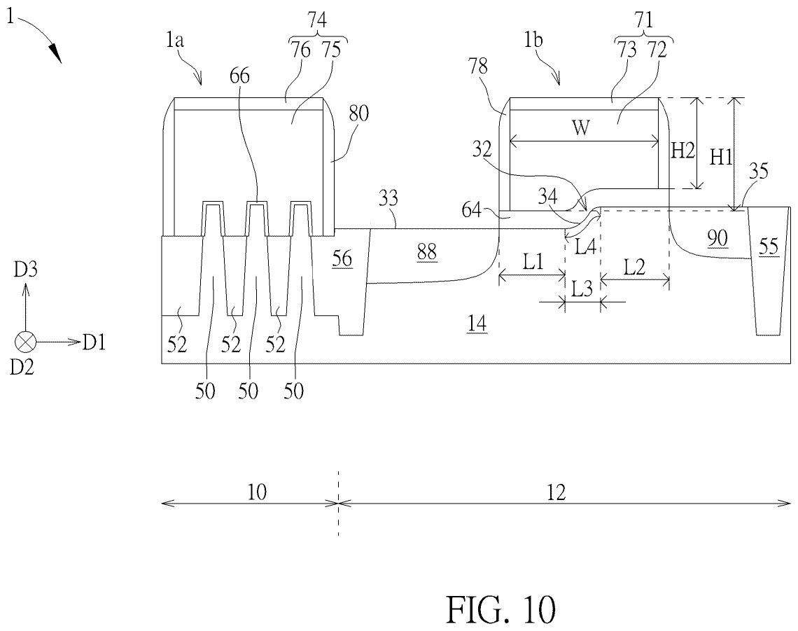

Please refer to FIG. 1 to FIG. 10, which are schematic cross-sectional views showing steps for fabricating a semiconductor device 1 (see FIG. 10) according to an embodiment of the present disclosure. First, as shown in FIG. 1, a substrate 14 is provided. At this stage, the substrate 14 may be regarded as an initial substrate. The substrate 14 includes a flat top surface 141. The substrate 14 may have a first region 10 and a second region 12. The substrate 14 may be a silicon substrate, an epitaxial silicon substrate, a silicon carbide substrate or a silicon on insulator (SOI) substrate. The difference between the first region 10 and the second region 12 is that the first region 10 and the second region 12 are configured to disposed devices with different operation voltages. The first region 10 may be, for example, a low voltage device region. The second region 12 may be, for example, a medium-high voltage device region. In general, taking a display chip as an example, the low voltage device region includes, for example, logic circuits, and an operation voltage thereof is less than or equal to 5 volts, and preferably within 1.5 volts. The operation voltage of the electronic devices disposed in the medium-high voltage device region is greater than 5 volts, and is usually greater than 10 volts. For example, a driving device of the display chip which requires a higher voltage to drive other devices of the display chip is the medium-high voltage device of the present disclosure.

Next, a mask layer 15 is formed to partially cover the top surface 141. Specifically, the mask layer 15 has an opening 18 to expose a portion of the substrate 14. The mask layer 15 may include a first sub-layer 16 and a second sub-layer 17. A material of the first sub-layer 16 may include an oxide such as silicon dioxide, and a material of the second sub-layer 17 may include a nitride such as silicon nitride, but not limited thereto.

Next, as shown in FIG. 2, the portion of the substrate 14 exposed from the mask layer 15 may be oxidized through a thermal oxidation process P1 to obtain an oxide layer 22. For example, the thermal oxidation process P1 may be performed in an oxygen-containing environment. The oxygen-containing environment may be achieved by introducing oxygen or oxygen-containing gas (such as water vapor) into the process chamber of the thermal oxidation process P1. The thermal oxidation process P1 may include an in-situ steam generation (ISSG) oxidation process, a wet furnace oxidation process, or a dry furnace oxidation process, but not limited thereto. In the thermal oxidation process P1, oxygen atoms of the oxygen-containing gas enter into the substrate 14 and combine with the silicon atoms in the substrate 14, so that the surface layer (not labeled) of the substrate 14 corresponding to the opening 18 is oxidized to form the oxide layer 22. Therefore, after the thermal oxidation process P1 is performed, the top surface 141 of the substrate 14 corresponding to the opening 18 is lowered, the top surface (not labeled) of the oxide layer 22 is higher than the top surface 141 (see FIG. 1) of the substrate 14 before performing the thermal oxidation process P1, and the bottom surface (not labeled) of the oxide layer 22 is lower than the top surface 141 (see FIG. 1) of the substrate 14 before performing the thermal oxidation process P1. In addition, due to the shielding of the mask layer 15, the portions of the oxide layer 22 connected with the first sub-layer 16 are formed with bird's beak structures 24 and 26. The thickness (not labeled) of each of the bird's beak structures 24 and 26 gradually decreases from the oxide layer 22 to the first sub-layer 16.

Next, as shown in FIG. 3, one or more etching processes may be performed to remove the oxide layer 22 and the mask layer 15 to form step structures 32 and 36 in the substrate 14. At this stage, a recess 31 is formed on the top surface 141 of the substrate 14, and two ends of the recess 31 respectively include the step structures 32 and 36. The step structure 32 includes a first step portion 33, a connecting portion 34 and a second step portion 35 arranged sequentially along a first horizontal direction D1, and the second step portion 35 is higher than the first step portion 33, in which the first step portion 33 may correspond to the bottom of the recess 31, the connecting portion 34 may correspond to the right sidewall of the recess 31, and the second step portion 35 may correspond to the region outside the right sidewall of the recess 31. The step structure 36 includes a first step portion 33, a connecting portion 38 and a second step portion 39 arranged sequentially along a direction opposite to the first horizontal direction DI, and the second step portion 39 is higher than the first step portion 33, in which the first step portion 33 may correspond to the bottom of the recess 31, the connecting portion 38 may correspond to the left sidewall of the recess 31, and the second step portion 39 may correspond to the region outside the left sidewall of the recess 31. The aforementioned first horizontal direction D1 may be, for example, parallel to the top surface 141 of the substrate 14 at the initial stage (see FIG. 1).

As shown in FIG. 3, in the step structure 32, the connecting portion 34 includes an inclined surface (not labeled). According to an embodiment of the present disclosure, an inclined angle Al of the inclined surface may be greater than or equal to 16 degrees and less than or equal to 24 degrees. In addition, the connecting portion 34 may include an arc-shaped profile. For example, the side of the connecting portion 34 adjacent to the first step portion 33 may include an arc-shaped profile which is concave upwardly, and the side of the connecting portion 34 adjacent to the second step portion 35 may include an arc-shaped profile which is convex upwardly. The aforementioned inclined surface refers to that a surface is inclined relative to a horizontal surface, and the horizontal surface may, for example, be parallel to the top surface 141 of the substrate 14 at the initial stage (see FIG. 1). The aforementioned inclined angle Al may be the included angle between the inclined surface and the horizontal surface. When the inclined surface includes the arc-shaped profile, the aforementioned inclined angle Al may be an included angle between the tangent plane at any point on the inclined surface and the horizontal surface.

In FIG. 3, there is a step difference d1 between the first step portion 33 and the second step portion 35. According to an embodiment of the present disclosure, the step difference d1 may be greater than 0 angstrom. Alternatively, the step difference d1 may be greater than 0 angstrom and less than or equal to 250 angstroms. The aforementioned step difference d1 may be the shortest distance between the first step portion 33 and the second step portion 35 in the vertical direction D3. The vertical direction D3 may be, for example, perpendicular to the top surface 141 of the substrate 14 at the initial stage (see FIG. 1).

Similarly, in the step structure 36, the connecting portion 38 may include an inclined surface. The step structure 36 and the step structure 32 may be symmetrical to each other. For other details about the step structure 36, references may be made to that of the step structure 32, and are omitted herein.

Next, as shown in FIG. 4, a plurality of fin structures 50 and a trench 51 are formed in the first region 10 of the substrate 14. Herein, three fin structures 50 are formed, which is exemplary, and the present disclosure is not limited thereto. The trench 51 surrounds the fin structures 50. The plurality of fin structures 50 are spaced apart from each other along the first horizontal direction D1, and each of the fin structures 50 extends along a second horizontal direction D2 perpendicular to the first horizontal direction D1. The aforementioned “each of the fin structures 50 extends along the second horizontal direction D2” may refer that the length of each of the fin structures 50 in the second horizontal direction D2 is greater than the length of each of the fin structures 50 in the first horizontal direction D1. The fin structures 50 may be formed, for example, by firstly forming the patterned mask 40 on the substrate 14, and then performing an etching process to transfer the pattern of the patterned mask 40 to the substrate 14 to form the fin structures 50 and the trench 51. The patterned mask 40 may include a first mask layer 42 and a second mask layer 44. The material of the first mask layer 42 may include an oxide such as silicon dioxide, and the material of the second mask layer 44 may include a nitride such as silicon nitride, but not limited thereto. Alternatively, the fin structures 50 may be formed by a sidewall image transfer (SIT) technology. The sidewall image transfer technology is well known to those skilled in the art, and is omitted herein.

Next, processes, such as deposition and planarization, may be performed to fill a dielectric material into the trench 51 and the recess 31 to respectively form insulating structures 52 and 53 in the trench 51 and the recess 31. The insulating structure 52 surrounds the fin structures 50.

Next, as shown in FIG. 5, a trench 54 is formed in the second region 12 of the substrate 14 to surround the active area of the second region 12. In FIG. 5, the left portion and the right portion of the trench 54 are shown, in which the left portion of the trench 54 is communicated with the trench 51 and the recess 31. Next, processes, such as deposition and planarization, may be performed to fill a dielectric material into the trench 54 to form an insulating structure 55 in the trench 54. The insulating structures 52 and 55 located at the boundary of the first region 10 and the second region 12 together form the insulating structure 56. The insulating structures 52, 55 and 56 may be, for example, shallow trench isolations (STI), which may be configured to provide an electrical isolation function. The insulating structures 52, 55 and 56 may include a dielectric material such as silicon dioxide. In this embodiment, the insulating structure 52 is formed first, and then the insulating structure 55 is formed. However, the present disclosure is not limited thereto. In other embodiments, the insulating structure 55 may be formed first, and then the insulating structure 52 is formed. Alternatively, the trenches 51 and 54 may be formed first, and then the dielectric material is deposited and the planarization process is performed to form the insulating structures 52 and 55 simultaneously.

As shown in FIG. 5, at this stage, the step structure 36 (see FIG. 3) of the substrate 14 has been removed, and only the step structure 32 is reserved. In addition, at this stage, the top surface 501 of the fin structure 50 is aligned with the top surface 351 of the second step portion 35.

Next, as shown in FIG. 6, the insulating structure 53 and parts of the insulating structures 52 and 56 may be removed through an etching process to expose the second mask layer 44 located below the insulating structure 53 and to expose the side surfaces (not labeled) of the second mask layer 44 on the fin structures 50. Next, as shown in FIG. 7, another etching process may be performed to remove the second mask layer 44 of the patterned mask 40 and expose the first mask layer 42 of the patterned mask 40. At this stage, the top surface 501 of the fin structure 50 is still aligned with the top surface 351 of the second step portion 35.

Next, as shown in FIG. 8, a patterned mask (not shown) may be formed to cover the first region 10 and expose only the second region 12, and a gate insulating material layer 60 may be formed in the second region 12 of the substrate 14. For example, the first mask layer 42 in the second region 12 may be removed first through an etching process, and then a thermal oxidation process may be performed to oxidize the step structure 32 to form the gate insulating material layer 60. In this case, the gate insulating material layer 60 may include silicon dioxide. After the thermal oxidation process is performed, the height of the top surface 141 of the substrate 14 is lowered. Moreover, the bottom surface (not labeled) of the gate insulating material layer 60 is slightly lower than the top surface 141 (see FIG. 7) of the substrate 14 before performing the thermal oxidation process, and the top surface (not labeled) of the gate insulating material layer 60 is slightly higher than the top surface 141 (see FIG. 7) of the substrate 14 before performing the thermal oxidation process. In addition, the dimension of the step difference d1 (see FIG. 3) between the first step portion 33 and the second step portion 35 may be maintained.

In other embodiments, the thermal oxidation process may be directly performed without removing the first mask layer 42, and the parameters of the thermal oxidation process may be controlled to allow the oxygen atoms of the oxygen-containing gas to penetrate the first mask layer 42 to combine with the silicon atoms in the substrate 14 below the first mask layer 42 to form an oxide, and the oxide and the first mask layer 42 together form the gate insulating material layer 60. Alternatively, a deposition process may be performed to form the gate insulating material layer 60. In this case, the top surface 141 of the substrate 14 has the same height before and after performing the deposition process. A material of the gate insulating material layer 60 may include an oxide or a nitride. The oxide may be, for example, silicon dioxide, and the nitride may be, for example, silicon nitride, but not limited thereto.

Please still refer to FIG. 8, a patterned mask (not shown) may be formed to cover the second region 12 and only expose the first region 10. Next, an etching process may be performed to remove the first mask layer 42 and parts of the insulating structures 52 and 56 located on the fin structures 50, so that the upper portions of the fin structures 50 are exposed. Next, a gate insulating material layer 62 is formed on the surfaces of the fin structures exposed from the insulating structures 52 and 56. The gate insulating material layer 62 may be formed by a thermal oxidation process. After the thermal oxidation process is performed, the sizes of the upper portions of the fin structures 50 exposed from the insulating structures 52 and 56 are slightly reduced. For example, the height of the top surface 501 of the fin structure 50 is slightly lowered. Moreover, the bottom surface (not labeled) of the gate insulating material layer 62 is slightly lower than the top surface 501 (see FIG. 7) of the fin structure 50 before performing the thermal oxidation process, and the top surface (not labeled) of the gate insulating material layer 62 is slightly higher than the top surface 501 (see FIG. 7) of the fin structure 50 before the performing thermal oxidation process. Alternatively, a deposition process may be performed to form the gate insulating material layer 62. In this case, the top surface 501 of the fin structure 50 has the same height before and after performing the deposition process. A material of the gate insulating material layer 62 may include an oxide or a nitride. The oxide may be, for example, silicon dioxide, and the nitride may be, for example, silicon nitride, but not limited thereto.

In this embodiment, both the gate insulating material layers 60 and 62 are formed by the thermal oxidation process. In the following processes, the gate insulating material layer 62 in the first region 10 is used to form the gate insulating layer 66 of the gate structure 74 (see FIG. 10) in the first region 10, and the gate insulating material layer 60 in the second region 12 is used to form the gate insulating layer 64 of the gate structure 71 (see FIG. 10) in the second region 12. Since the second region 12 is a medium-high voltage device region, and the first region 10 is a low voltage device region, the thickness of the gate insulating material layer 62 is configured to be smaller than the thickness of the gate insulating material layer 60. In other words, at this stage, the top surface 501 of the fin structure 50 is slightly higher than the top surface 351 of the second step portion 35.

Next, as shown in FIG. 9, the gate structure 74 is formed in the first region 10, and the gate structure 71 is formed in the second region 12. Specifically, the gate structure 71 is formed on the step structure 32, and is on the connecting portion 34. Moreover, the gate structure 71 is formed on the gate insulating material layer 60. The gate structures 71 and 74 may be formed in the same step. For example, a gate material and a mask material may be deposited sequentially on the substrate 14, and then parts of the mask material and the gate material may be removed by processes, such as planarization and patterning, to form the gate structures 74 and 71. The gate structure 74 includes a gate material layer 75 and a mask layer 76 from bottom to top. The gate structure 71 includes a gate material layer 72 and a mask layer 73 from the bottom to top. The gate material layers 72 and 75 may include a non-metallic conductive material such as polycrystalline silicon. The mask layer 76 may include a nitride such as silicon nitride. Since the gate structures 71 and 74 may be formed in the same step, the top surface of the gate structure 74 may be aligned with the top surface of the gate structure 71.

Next, light doped drains (LDDs) (not shown) may be formed in the portions of the fin structure 50 located at two sides of the gate structure 74. Next, light doped drains (not shown) may be formed in the portions of the substrate 14 located at two sides of the gate structure 71.

Next, as shown in FIG. 10, a spacer material is formed to cover the top surfaces and the side surfaces of the gate structures 71 and 74, and to cover the portion of substrate 14 not covered by the gate structures 71 and 74. Next, a patterned mask (not shown) is firstly formed to cover the second region 12 and expose only the first region 10. The spacer material located on the top surface of the gate structure 74, the spacer material located on the fin structures 50 at two sides of the gate structure 74, the portions not shown) of the gate insulating material layer 62 located at two sides of the gate structure 74, and the portions (not shown) of the fin structures 50 located at two sides of the gate structure 74 and protruding from the insulating structures 52 and 56 are removed, and the top ends (not shown) of the fin structures 50 at two sides of the gate structure 74 are slightly recessed relative to the insulating structures 52 and 56. Next, a selective epitaxial growth process is performed to form a plurality of epitaxial structures (not shown) on the fin structures at two sides of the gate structure 74. The plurality of epitaxial structures may be merged to each other. After the portions of the gate insulating material layer 62 located at two sides of the gate structure 74 are removed, the remaining portion of the gate insulating material layer 62 forms the gate insulating layer 66 (i.e., the portion of the gate insulating material layer 62 located below the gate structure 74). The unremoved portion of the spacer material located on the side surfaces of the gate structure 74 forms the spacer 80. The spacer 80 surrounds the side surfaces of the gate structure 74.

In this embodiment, when forming the epitaxial structure, an ion implanting process and an annealing process may be performed in-situ to form source/drain (not labeled) in the epitaxial structures at two sides of the gate structure 74. In other embodiments, the ion implantation process and the annealing process may be performed to form the source/drain in the epitaxial structures at two sides of the gate structure 74 after the epitaxial structures are formed. Thereby, the fabrication of the semiconductor device la is completed. The dopants of the epitaxial structures may be adjusted depending on the semiconductor device 1a being applied to an n-type metal oxide semiconductor (NMOS) transistor or a p-type metal oxide semiconductor (PMOS) transistor. For example, when the semiconductor device 1a is applied to the NMOS transistor, the epitaxial structures may have N-type impurities, such as arsenic and phosphorus. When the semiconductor device 1a is applied to the PMOS transistor, the epitaxial structures may have p-type impurities, such as boron and indium.

Next, a patterned mask (not shown) is formed to cover the first region 10 and only expose the second region 12. The spacer material located on the top surface of the gate structure 71, and the spacer material located on the substrate 14 at two sides of the gate structure 71 are removed. The portion of the gate insulating material layer 60 not covered by the gate structure 71 is removed to form the gate insulating layer 64. The gate insulating layer 64 is located between the substrate 14 and the gate structure 71. Since the gate insulating layer 64 conformally covers the step structure 32, the gate insulating layer 64 also includes a step structure (not labeled). The unremoved portion of the spacer material located on the side surfaces of the gate structure forms the spacer 78, and the spacer 78 surrounds the side surfaces of the gate structure 71.

Next, a drain region 88 and a source region 90 are formed in the substrate 14 at two sides of the gate structure 71. Specifically, the drain region 88 is formed in the first step portion 33, and the source region 90 is formed in the second step portion 35. The dopants of the drain region 88 and the source region 90 may be adjusted depending on the semiconductor device 1b being applied to the NMOS transistor or the PMOS transistor. For the dopants of the NMOS transistor and the PMOS transistor, references may be made to above description, and are omitted herein. Thereby, the fabrication of the semiconductor device 1b is completed. Although not shown in the drawings, a dielectric layer may be formed by a deposition process and a planarization process according to actual needs. The dielectric layer is disposed on the substrate 14 and surrounds the gate structures 71 and 74, and a top surface of the dielectric layer is aligned with the top surfaces of the gate structures 71 and 74. Moreover, a replacement metal gate (RMG) process may be performed to replace the gate material layers 72 and 75 with metal gate material layers. The replacement metal gate process is well known to those skilled in the art, and is omitted herein.

Each of the spacers 78 and 80 may be a single-layer structure or a multi-layer structure, and the materials of the spacers 78 and 80 may include oxides and/or nitrides, such as silicon dioxide, silicon nitride, silicon oxynitride or silicon carbonitride.

The aforementioned film layers, such as the first sub-layer 16, the second sub-layer 17, the first mask layer 42, the second mask layer 44, the insulating structures 52, 53 and 55, the gate material layers 72 and 75, the mask layers 73 and 76, the spacers 78 and 80, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE), atomic layer deposition (ALD).

Please refer to FIG. 10, which is a schematic cross-sectional view showing the semiconductor device 1 according to an embodiment of the present disclosure. The semiconductor device 1 includes the semiconductor device 1a and the semiconductor device 1b. The semiconductor device 1a is disposed in the first region 10 of the substrate 14. The semiconductor device 1b is disposed in the second region 12 of the substrate 14. The semiconductor device 1a may be a low voltage device, and the semiconductor device 1b may be a medium-high voltage device.

The semiconductor device 1a includes the substrate 14, the plurality of fin structures 50, the gate insulating layer 66, the gate structure 74 and the spacer 80. The fin structures 50 are formed on the substrate 14, and the gate structure 74 is disposed on the fin structures 50 through the gate insulating layer 66. The spacer 80 surrounds the side surfaces of the gate structure 74.

The semiconductor device 1b includes the substrate 14, the gate structure 71, the drain region 88 and the source region 90. The substrate 14 includes the step structure 32, the step structure 32 includes the first step portion 33, the connecting portion 34, and the second step portion 35 arranged sequentially along the first horizontal direction D1, and the second step portion 35 is higher than the first step portion 33. The gate structure 71 is disposed on the connecting portion 34, the drain region 88 is disposed in the first step portion 33, and the source region 90 is disposed in the second step portion 35.

Specifically, the gate structure 71 is also disposed on the first step portion 33 and the second step portion 35. That is, the first step portion 33 includes the first portion (not labeled) located below the gate structure 71, and the second step portion 35 includes the second portion (not labeled) located below the gate structure 71. According to an embodiment of the present disclosure, the length L1 of the first portion in the first horizontal direction D1 may be the same as the length L2 of the second portion in the first horizontal direction D1. According to an embodiment of the present disclosure, the length L1 of the first portion in the first horizontal direction D1 may be greater than or equal to the length L3 of the connecting portion 34 in the first horizontal direction D1. According to an embodiment of the present disclosure, the length L2 of the second portion in the first horizontal direction D1 may be greater than or equal to the length L3 of the connecting portion 34 in the first horizontal direction D1.

In the present disclosure, by disposing the drain region 88 in the first step portion 33 and the source region 90 in the second step portion 35, the distance between the drain region 88 and the source region 90 can be increased. As shown in FIG. 10, the distance between the drain region 88 and the source region 90 may be equal to the sum of the length L1, the length L4 of the connecting portion 34, and the length L2. Compared with a semiconductor device having the drain region 88 and the source region 90 disposed at the same level (i.e., at the same height), the semiconductor device 1b according to the present disclosure may increase the distance between the drain region 88 and the source region 90 due to the length L4 being greater than the length L3. Thereby, it is beneficial to reduce the probability of punch-through. When the distance between the drain region 88 and the source region 90 is fixed, the semiconductor device 1b according to the present disclosure can reduce the width W of the gate structure 71 in the first horizontal direction D1, which is beneficial to reduce the dimension of the semiconductor device 1b.

The connecting portion 34 may include an arc-shaped profile. The connecting portion 34 may include an inclined surface (not labeled), and an inclined angle A1 (see FIG. 3) of the inclined surface may be greater than or equal to 16 degrees and less than or equal to 24 degrees. There may be a step difference d1 (see FIG. 3) between the first step portion 33 and the second step portion 35, and the step difference d1 may be greater than 0 angstrom, or the step difference d1 may be greater than 0 angstrom and less than or equal to 250 angstroms.

The gate structure 71 may include an asymmetric profile. In addition, the gate structure 71 has a first height H1 closer to the drain region 88 and a second height H2 closer to the source region 90, and the first height H1 may be greater than the second height H2.

The semiconductor device 1a may further include a gate insulating layer 64 disposed between the gate structure 71 and the substrate 14. The gate insulating layer 64 may also include a step structure (not labeled). For other details of the semiconductor devices 1, 1aand 1b, references may be made to the above description, and are omitted herein.

Compared with the prior art, in the present disclosure, with the position of the drain region being lower than the position of the source region, it is beneficial to lower the depletion region and increase the distance between the drain region and the source region. Thereby, it can reduce the probability of punch-through.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate comprising a first step structure, wherein the first step structure comprises a first step portion, a connecting portion and a second step portion arranged sequentially along a direction, and the second step portion is higher than the first step portion;
a gate structure disposed on the connecting portion;
a drain region disposed in the first step portion; and
a source region disposed in the second step portion.

2. The semiconductor device of claim 1, wherein the connecting portion comprises an arc-shaped profile.

3. The semiconductor device of claim 1, wherein the connecting portion comprises an inclined surface, and an inclined angle of the inclined surface is greater than or equal to 16 degrees and less than or equal to 24 degrees.

4. The semiconductor device of claim 1, wherein there is a step difference between the first step portion and the second step portion, and the step difference is greater than 0 angstrom and less than or equal to 250 angstroms.

5. The semiconductor device of claim 1, wherein the gate structure has a first height closer to the drain region and a second height closer to the source region, and the first height is greater than the second height.

6. The semiconductor device of claim 1, wherein the gate structure comprises an asymmetric profile.

7. The semiconductor device of claim 1, wherein the first step portion comprises a first portion located below the gate structure, and the second step portion comprises a second portion located below the gate structure.

8. The semiconductor device of claim 7, wherein a length of the first potion in the direction is the same as a length of the second portion in the direction.

9. The semiconductor device of claim 7, wherein a length of the first portion in the direction is greater than or equal to a length of the connecting portion in the direction.

10. The semiconductor device of claim 1, further comprising:
a gate insulating layer disposed between the gate structure and the substrate, wherein the gate insulating layer comprises a second step structure.

11. The semiconductor device of claim 1, further comprising:
a fin structure disposed in a first region of the substrate, wherein the first step structure is disposed in a second region of the substrate, and a top surface of the fin structure is higher than a top surface of the second step portion.

12. A method for fabricating a semiconductor device, comprising:
providing a substrate, wherein the substrate comprises a first step structure, the first step structure comprises a first step portion, a connecting portion and a second step portion arranged sequentially along a direction, and the second step portion is higher than the first step portion;
forming a gate structure on the connecting portion;
forming a drain region in the first step portion; and
forming a source region in the second step portion.

13. The method of claim 12, wherein the connecting portion comprises an arc-shaped profile.

14. The method of claim 12, wherein the connecting portion comprises an inclined surface, and an inclined angle of the inclined surface is greater than or equal to 16 degrees and less than or equal to 24 degrees.

15. The method of claim 12, wherein there is a step difference between the first step portion and the second step portion, and the step difference is greater than 0 angstrom and less than or equal to 250 angstroms.

16. The method of claim 12, wherein the gate structure has a first height closer to the drain region and a second height closer to the source region, and the first height is greater than the second height.

17. The method of claim 12, further comprising:
providing an initial substrate, wherein the initial substrate comprises a flat top surface;
forming a mask layer to partially cover the flat top surface;
oxidizing a portion of the initial substrate exposed from the mask layer to obtain an oxide layer; and
removing the oxide layer to form the first step structure.

18. The method of claim 12, further comprising:
forming a gate insulating layer between the substrate and the gate structure, wherein the gate insulating layer comprises a second step structure.

19. The method of claim 18, further comprising:
oxidizing the first step structure to form a gate insulating material layer;
forming the gate structure on the gate insulating material layer; and
removing a portion of the gate insulating material layer not covered by the gate structure to form the gate insulating layer.

20. The method of claim 11, further comprising:
forming a fin structure in a first region of the substrate, wherein the first step structure is disposed in a second region of the substrate, and a top surface of the fin structure is higher than a top surface of the second step portion.
